(19) United States
(12) Patent Application Publication
(10) Pub. No.: US 2022/0308126 A1
(43) Pub. Date: Sep. 29, 2022

(54) MAGNETIC SENSOR

(71) Applicant: SHOWA DENKO K.K., Tokyo (JP)

(72) Inventors: Hiroyuki TOMITA, Ichihara-shi (JP); Isao KABE, Ichihara-shi (JP)

(73) Assignee: SHOWA DENKO K.K., Tokyo (JP)

(21) Appl. No.: 17/688,363

(22) Filed: Mar. 7, 2022

(30) Foreign Application Priority Data
Mar. 24, 2021 (JP) 2021-050699

(51) Int. Cl. G01R 33/06; G01R 33/00

(52) U.S. Cl. CPC G01R 33/063; G01R 33/0029

(57) ABSTRACT

In a magnetic sensor using sensitive circuits sensing magnetic fields by the magnetic impedance effect, a sensitivity-to-noise ratio is improved. A magnetic sensor 10 includes: a sensitive circuit 12A including sensitive parts sensing magnetic fields by magnetic impedance effect; and a sensitive circuit 12B including sensitive parts sensing magnetic fields by magnetic impedance effect, wherein at least a part of current paths of the sensitive circuit 12A and at least a part of current paths of the sensitive circuit 12B overlap in a plan view, and one end portion of the sensitive circuit 12A and one end portion of the sensitive circuit 12B are electrically connected.

### CROSS REFERENCE TO RELATED APPLICATIONS

This application is based on and claims priority under 35 USC § 119 to Japanese Patent Application No. 2020-050699 filed Mar. 24, 2021, the disclosure is incorporated herein by reference in its entirety.

### BACKGROUND

### Technical Field

The present invention relates to a magnetic sensor.

### Related Art

As a related art described in a gazette, there is a magnetic impedance element including a substrate made of a non-magnetic material, a thin-film magnetic core formed on the substrate, and first and second electrodes disposed on both ends of the thin-film magnetic core in a longitudinal direction, wherein at least two thin-film magnetic cores are disposed in parallel and electrically connected in series with each other (refer to Japanese Patent Application Laid-Open Publication No. 2000-292506).

In a magnetic sensor using a sensitive circuit sensing the magnetic field by the magnetic impedance effect, the change in the impedance is detected by a detection part and converted into the magnetic field strength. However, since terminal parts supplying alternating current to the sensitive circuit are provided at both end portions of the sensitive circuit, a large current loop is formed between the terminal parts and the detection part. The current loop generates noise and also picks up noise. Such noise reduces the sensitivity-to-noise ratio (S/N ratio) of the magnetic sensor.

An object of the present invention is to improve a sensitivity-to-noise ratio of a magnetic sensor using a sensitive circuit sensing a magnetic field by the magnetic impedance effect.

### SUMMARY

A magnetic sensor to which the present invention is applied includes: a first sensitive circuit including a sensitive part sensing a magnetic field by magnetic impedance effect; and a second sensitive circuit including a sensitive part sensing a magnetic field by magnetic impedance effect, wherein at least a part of a current path of the first sensitive circuit and at least a part of a current path of the second sensitive circuit overlap in a plan view, and one end portion of the first sensitive circuit and one end portion of the second sensitive circuit are electrically connected.

In such a magnetic sensor, currents in portions, which overlap and face each other, of the respective first and second sensitive circuits may have opposite flowing directions.

Each of the first sensitive circuit and the second sensitive circuit may have a winding structure.

Further, the first sensitive circuit and the second sensitive circuit may have a same planar shape in a plan view in a state where the first and second sensitive circuits face each other.

In such a magnetic sensor, the first sensitive circuit may be provided on a non-magnetic first substrate and the second sensitive circuit may be provided on a non-magnetic second substrate.

Alternatively, the first sensitive circuit may be provided on a front side of a non-magnetic substrate and the second sensitive circuit may be provided on a back side of the substrate.

In such a magnetic sensor, the first sensitive circuit and the second sensitive circuit may be connected in series.

From another standpoint, a magnetic sensor to which the present invention is applied includes: a sensitive circuit including a sensitive part sensing a magnetic field by magnetic impedance effect; and a current circuit configured with a non-magnetic conductive material, wherein at least a part of a current path of the sensitive circuit and at least a part of a current path of the current circuit overlap in a plan view, and one end portion of the sensitive circuit and one end portion of the current circuit are electrically connected.

In such a magnetic sensor, the sensitive circuit may be provided on a non-magnetic first substrate and the current circuit may be provided on a non-magnetic second substrate.

Alternatively, the sensitive circuit may be provided on a front side of a non-magnetic substrate and the current circuit may be provided on a back side of the substrate.

Moreover, such a magnetic sensor may further include a focusing member configured with a soft magnetic material and focusing magnetic force lines from outside onto the sensitive circuit.

The above magnetic sensor may further include a diverging member configured with a soft magnetic material and diverging the magnetic force lines passed through the sensitive circuit to the outside.

Still further, the focusing member and the diverging member may be provided outside of the substrate on which the sensitive circuit is provided.

According to the present invention, it is possible to improve a sensitivity-to-noise ratio of a magnetic sensor using a sensitive circuit sensing a magnetic field by the magnetic impedance effect.

### BRIEF DESCRIPTION OF THE DRAWINGS

Exemplary embodiments of the present invention will be described in detail based on the following figures, wherein:

FIGS. 1A and 1B illustrate a magnetic sensor system measuring the magnetic field by a magnetic sensor, where FIG. 1A shows a magnetic sensor system using a magnetic sensor to which a first exemplary embodiment is applied, and FIG. 1B shows, for a comparative purpose, a magnetic sensor system using a magnetic sensor to which the first exemplary embodiment is not applied;

FIG. 2 shows, in the magnetic sensor shown in FIG. 1B, a relation between an area of a current loop formed by wiring in the neighborhood of the magnetic sensor and an inductance generated by the magnetic sensor and the current loop;

FIGS. 3A and 3B illustrate an example of a sensitive circuit, where FIG. 3A is a plan view and FIG. 3B is a cross-sectional view along the IIIB-IIIB line in FIG. 3A;

FIG. 4 illustrates a relation between an external magnetic field applied in the longitudinal direction of a sensitive part of the sensitive circuit and an impedance of the sensitive circuit;

FIGS. 5A and 5B illustrate a configuration of the magnetic sensor to which the first exemplary embodiment is applied, where FIG. 5A is a perspective view of the magnetic sensor and FIG. 5B illustrates the current and the magnetic field in the sensitive circuit;

FIGS. 6A to 6D illustrate manners of overlapping two sensitive circuits in the magnetic sensor, where FIG. 6A shows disposition of the two sensitive circuits facing each other inside the substrates, FIG. 6B shows disposition of the two sensitive circuits facing each other outside the substrates, FIG. 6C shows disposition of the two sensitive circuits piled on the respective substrates, and FIG. 6D shows disposition of the two sensitive circuits provided on the front and back of a single substrate;

FIGS. 7A and 7B illustrate the sensitivity in the magnetic sensor in which the two sensitive circuits are overlapped, where FIG. 7A shows a relation between the area of the current loop and the sensitivity, and FIG. 7B shows a relation between the distance of the two sensitive circuits and the sensitivity;

FIG. 8 illustrates the sensitivity in the magnetic sensor in which the two sensitive circuits are overlapped;

FIG. 9 illustrates a magnetic sensor including a focusing member that focuses magnetic force lines and a diverging member that diverges the magnetic force lines to the outside;

FIG. 10 illustrates a relation among the configuration, the sensitivity, the noise, and the sensitivity-to-noise ratio of the magnetic sensor;

FIGS. 11A and 11B illustrate a configuration of the magnetic sensor to which a second exemplary embodiment is applied, where FIG. 11A is a perspective view of the magnetic sensor, and FIG. 11B illustrates the currents and the magnetic fields in the sensitive circuit and a current circuit; and

FIGS. 12A and 12B are diagrams illustrating the magnetic sensor to which the first exemplary embodiment is applied and the magnetic sensor to which the second exemplary embodiment is applied by comparison thereof, where FIG. 12A is a cross-sectional view of the magnetic sensor to which the second exemplary embodiment is applied, and FIG. 12B is a cross-sectional view of the magnetic sensor to which the first exemplary embodiment is applied.

### DETAILED DESCRIPTION

Hereinafter, exemplary embodiments according to the present invention will be described with reference to attached drawings.

### First Exemplary Embodiment

### (Magnetic Sensor System 1)

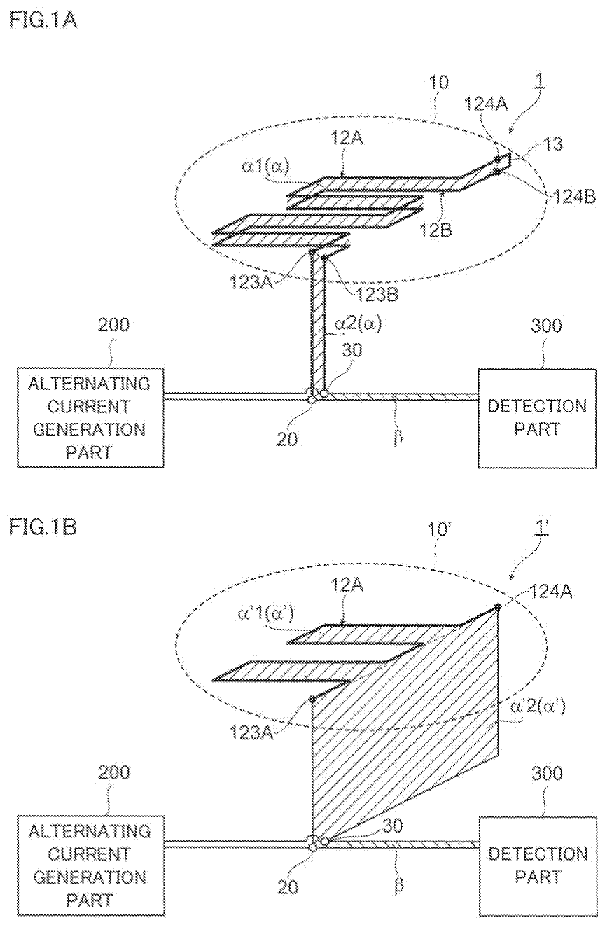

FIGS. 1A and 1B illustrate a magnetic sensor system 1 measuring the magnetic field by a magnetic sensor 10. FIG. 1A shows a magnetic sensor system 1 using a magnetic sensor 10 to which the first exemplary embodiment is applied, and FIG. 1B shows, for a comparative purpose, a magnetic sensor system 1′ using a magnetic sensor 10′ to which the first exemplary embodiment is not applied.

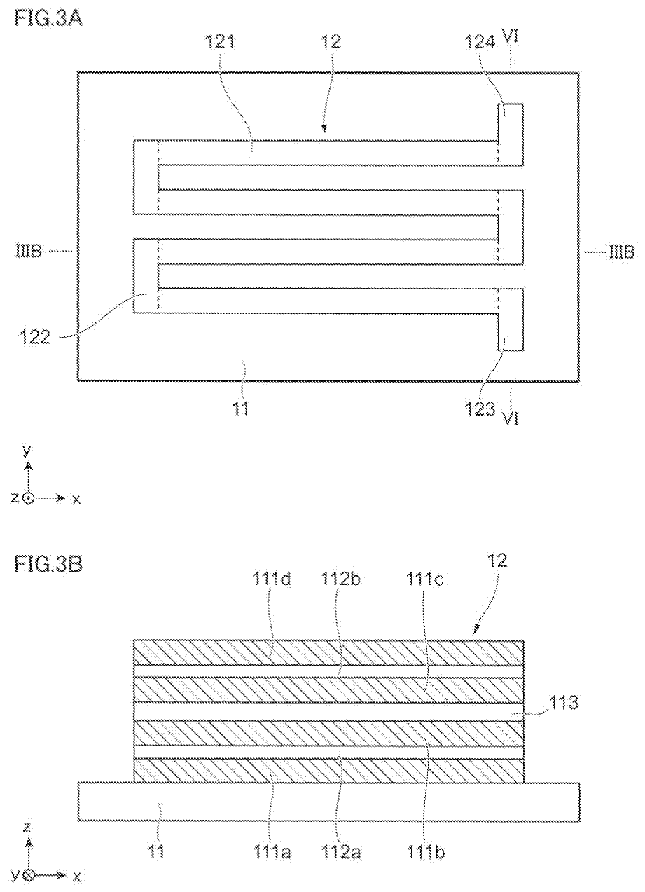

The magnetic sensor system 1 shown in FIG. 1A, which uses the magnetic sensor 10 to which the first exemplary embodiment is applied, includes the magnetic sensor 10 sensing the magnetic field, an alternating current generation part 200, and a detection part 300. The magnetic sensor 10 is connected to the alternating current generation part 200 and the detection part 300 via connection terminals 20 and 30, respectively. The magnetic sensor 10 is provided with sensitive circuits 12A and 12B, each including sensing parts 121 (refer to FIG. 3A to be described later), in which the impedance changes due to changes in the magnetic field based on the magnetic impedance effect. The sensitive circuits 12A and 12B are overlapped. The sensitive circuit 12A is an example of a first sensitive circuit, and the sensitive circuit 12B is an example of a second sensitive circuit.

The sensitive circuit 12A includes terminal parts 123A and 124A, and the sensitive circuit 12B includes terminal parts 123B and 124B. The terminal part 124A of the sensitive circuit 12A and the terminal part 124B of the sensitive circuit 12B are connected by a connection line 13. The sensitive circuits 12A and 12B are connected in series. Then, the terminal part 123A of the sensitive circuit 12A is connected to the connection terminal 20, and the terminal part 123B of the sensitive circuit 12B is connected to the connection terminal 30. In the magnetic sensor 10, the current flows between the terminal part 123A of the sensitive circuit 12A and the terminal part 123B of the sensitive circuit 12B. Since the sensitive circuits 12A and 12B are connected in series, the directions of the current flow are opposite.

As shown in FIG. 1A, the distance between the centers of the terminal part 123A of the sensitive circuit 12A and the terminal part 123B of the sensitive circuit 12B is short compared to the distance between the centers of the terminal part 123A of the sensitive circuit 12A and the terminal part 124A of the sensitive circuit 12A or the distance between the centers of the terminal part 123A of the sensitive circuit 12A and the terminal part 124B of the sensitive circuit 12B.

As shown in FIG. 1B, the magnetic sensor system 1′, which uses the magnetic sensor 10′ to which the first exemplary embodiment is not applied, includes the magnetic sensor 10′ sensing the magnetic field, the alternating current generation part 200, and the detection part 300. The alternating current generation part 200 and the detection part 300 in the magnetic sensor system 1′ are the same as those in the magnetic sensor system 1 shown in FIG. 1A. The magnetic sensor 10′ is connected to the alternating current generation part 200 and the detection part 300 via the connection terminals 20 and 30, respectively. The magnetic sensor 10′ includes the sensitive circuit 12A. In other words, the magnetic sensor 10′ does not include the sensitive circuit 12B.

The terminal part 123A of the sensitive circuit 12A is connected to the connection terminal 20, and the terminal part 124A of the sensitive circuit 12A is connected to the connection terminal 30.

The sensitive circuits 12A and 12B have the same configuration. Accordingly, hereinafter, when the sensitive circuits 12A and 12B are not distinguished, these are referred to as the sensitive circuits 12.

The alternating current generation part 200 includes a circuit that generates an alternating current containing a high-frequency component (hereinafter, referred to as high-frequency current) and supplies the high-frequency current to the magnetic sensors 10 and 10′. Note that the high frequency is, for example, 20 MHz or more.

The detection part 300 includes a circuit that detects changes in inductance and changes in amplitude and phase of the impedance of the magnetic sensors 10 and 10′.

FIG. 1A shows a current loop α formed between the magnetic sensor 10 and the connection terminals 20 and 30, and a current loop β formed between the connection terminals 20 and 30 and the detection part 300 in the magnetic sensor system 1. Note that the current loop α is the current loop formed by wiring in the neighborhood of the magnetic sensor 10, and the current loop β is the current loop formed by wiring in the neighborhood of the detection part 300. Hereinafter, the current loop α is referred to as the current loop α formed by the wiring in the neighborhood of the magnetic sensor 10, and the current loop β is referred to as the current loop β formed by the wiring in the neighborhood of the detection part 300. The current loop, which is the addition of the current loop α and the current loop β, is the current loop surrounded by the magnetic sensor 10 and the detection part 300. The current loop functions as an inductance. Then, as the area of the current loop is increased, the inductance is also increased.

The current loop α formed by the wiring in the neighborhood of the magnetic sensor 10 is configured with a current loop α1 in the magnetic sensor 10 and a current loop α2 between the magnetic sensor 10 and the connection terminals 20 and 30. The current loop α1 in the magnetic sensor 10 is the current loop between the sensitive circuit 12A and the sensitive circuit 12B. In FIG. 1A, the current loop α1 and the current loop α2 are referred to as α1(α) and α2(α), respectively.

FIG. 1B shows a current loop α′ formed between the magnetic sensor 10′ and the connection terminals 20 and 30, and the current loop β formed between the connection terminals 20 and 30 and the detection part 300 in the magnetic sensor system 1′. The current loop β formed between the connection terminals 20 and 30 and the detection part 300, that is, the current loop β formed by the wiring in the neighborhood of the detection part 300, is the same as that of the magnetic sensor system 1 shown in FIG. 1A.

The current loop α′ formed by the wiring in the neighborhood of the magnetic sensor 10′ is configured with a current loop α′1 in the magnetic sensor 10′ and a current loop α′2 between the magnetic sensor 10′ and the connection terminals 20 and 30. The current loop α′1 in the magnetic sensor 10′ is the current loop in the sensitive circuit 12A. In FIG. 1B, the current loop α′1 and the current loop α′2 are referred to as α′1(α′) and α′2(α′), respectively.

The current loop α′ in the magnetic sensor system 1′ is different from the current loop α in the magnetic sensor system 1 shown in FIG. 1A. In other words, the area of the current loop α′ formed by the wiring in the neighborhood of the magnetic sensor 10′ is larger than the area of the current loop α formed by the wiring in the neighborhood of the magnetic sensor 10. This is because the area of the current loop α′2 between the magnetic sensor 10′ and the connection terminals 20 and 30 is larger than the area of the current loop α2 between the magnetic sensor 10 and the connection terminals 20 and 30. In the magnetic sensor system 1, the terminal parts 123A and 123B are connected to the connection terminals 20 and 30, respectively. On the other hand, in the magnetic sensor system 1′, the terminal parts 123A and 124A are connected to the connection terminals 20 and 30, respectively. The distance between the centers of the terminal parts 123A and 123B in the magnetic sensor system 1 (the magnetic sensor 10) is shorter than the distance between the centers of the terminal parts 123A and 124A in the magnetic sensor system 1′ (the magnetic sensor 10′). Therefore, the area of the current loop α2 is smaller than the area of the current loop α′2.

Further, the current loop α1 in the magnetic sensor 10 is the current loop between the sensitive circuit 12A and the sensitive circuit 12B that are disposed to be overlapped. On the other hand, the current loop α′1 in the magnetic sensor 10′ is the current loop in the sensitive circuit 12A. Since a current path, through which the current flows back and forth, is brought into contact with the current loop α1, the current loop α1 is smaller than the current loop α′1.

Here, description will be given of effects of the inductance by the current loop on the change in the inductance of the magnetic sensor system 1. Note that the description will be given by taking the magnetic sensor 10 shown in FIG. 1A as an example.

It is assumed that the inductance of the magnetic sensor 10 when the signal magnetic field is not applied is L1, and the amount of change in the inductance of the magnetic sensor 10 when the signal magnetic field is applied is ΔL1. Then, it is assumed that the inductance generated by the current loop α formed by the wiring in the neighborhood of the magnetic sensor 10 and the current loop β formed by the wiring in the neighborhood of the detection part 300 is L2. Note that the signal magnetic field is a magnetic field that is applied from the outside to the magnetic sensor 10 to explain the operation of the magnetic sensor 10. When the signal magnetic field is applied to the magnetic sensor 10, the impedance of the magnetic sensor 10 changes against the case where the signal magnetic field is not applied.

The inductance in the state where the signal magnetic field is not applied is L1+L2. The inductance in the state where the signal magnetic field is applied is L1+AL1+L2. Therefore, due to the application of the signal magnetic field, the rate of change in the inductance detected by the detection part 300 is (L1+ΔL1+L2)/(L1+L2). Consequently, as the inductance L2 is reduced, the rate of change in the inductance is increased. To put it another way, as the inductance L2 is reduced, the rate of change in the inductance is increased, and the sensitivity to detect the magnetic field is improved. In other words, reduction in the inductance L2 generated by the current loop α formed by the wiring in the neighborhood of the magnetic sensor 10 and the current loop β formed by the wiring in the neighborhood of the detection part 300 improves the sensitivity of the magnetic sensor 10.

In addition, the areas of the current loop α formed by the wiring in the neighborhood of the magnetic sensor 10 and the current loop β formed by the wiring in the neighborhood of the detection part 300 are increased, noise is likely to be generated, and noise is likely to be picked up. In other words, the high-frequency current flowing through the sensitive circuit 12 generates a magnetic field, and the generated magnetic field causes noise in the high-frequency current.

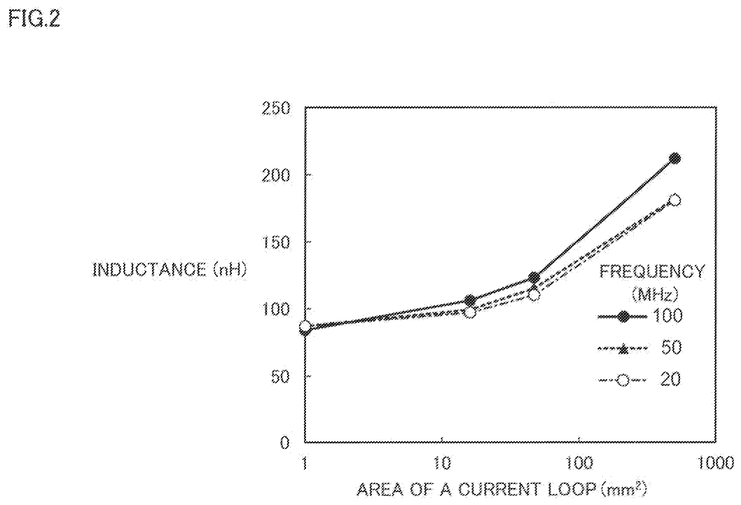

FIG. 2 shows, in the magnetic sensor 10′ shown in FIG. 1B, a relation between an area of a current loop α′ formed by wiring in the neighborhood of the magnetic sensor 10′ and an inductance generated by the magnetic sensor 10′ and the current loop α′. The horizontal axis is the area of the current loop α′ (in FIG. 2, the area of the current loop (mm²)), and the vertical axis is the inductance (nH). Here, the inductance was measured by connecting the terminal part 123 and the terminal part 124 of the magnetic sensor 10, shown in FIG. 3 to be described later, to an impedance measuring device. At this time, the area surrounded by the wires connecting the terminal part 123 and the terminal part 124 to the impedance measuring device was changed. In FIG. 2, the frequencies at which the inductance is measured were set at 20 MHz, 50 MHz, and 100 MHz. Note that, in FIG. 2, since the area of the current loop α′1 in the magnetic sensor 10′ is smaller than the area of the current loop α′2 between the magnetic sensor 10′ and the connection terminals 20 and 30, the area of α′ was set at 0 mm².

As shown in FIG. 2, the inductance generated by the magnetic sensor 10′ and the current loop α′ is increased as the area of the current loop α′ is increased. In addition, the inductance generated by the magnetic sensor 10′ and the current loop α′ is increased as the frequency is increased. In other words, as the area of the current loop α′ is reduced, the inductance is also reduced.

Note that the detection part 300 may detect the change in the impedance including the inductance L, the resistance R, and the capacitance C instead of detecting the change in the inductance of the above-described magnetic sensor 10. For example, the detection part 300 may include a circuit that detects the amplitude and phase of the impedance. In this case, the impedance Z is represented as Z=R+jωL+1/(jωC)=R+jX. The amplitude |Z| is represented as |Z|=√R²+X²),and the phase θ is represented as θ=tan⁻¹(X/R). Here, ω is the angular frequency, and X is the reactance.

The area of the magnetic sensor 10′, which is configured to include the sensitive circuit 12 (refer to FIG. 3A to be described later) is more likely to be larger than the area of the electronic components constituting the alternating current generation part 200 and the detection part 300. Accordingly, as shown in FIG. 1B, the area of the current loop α′ formed by the wiring in the neighborhood of the magnetic sensor 10′, to which the terminal parts 123A and 124A of the sensitive circuit 12A and connection terminals 20 and 30 are connected, is more likely to be larger than the area of the current loop β formed by the wiring in the neighborhood of the detection part 300. Therefore, it is preferable to reduce the current loop α′ formed by wiring in the neighborhood of the magnetic sensor 10′. However, since the current loop α′1 in the magnetic sensor 10′ is determined by the shape of the magnetic sensor 10′, it is difficult to reduce the area of the current loop α′1 in the magnetic sensor 10′. In addition, the area of the current loop α′2 between the magnetic sensor 10 and the connection terminals 20 and 30 is more likely to be larger than the area of the current loop α′1 in the magnetic sensor 10′.

Consequently, in the magnetic sensor 10 (FIG. 1A) to which the first exemplary embodiment is applied, the area of the current loop α2 between the magnetic sensor 10 and the connection terminals 20 and 30 in the current loop α formed by the wiring in the neighborhood of the magnetic sensor 10 is made smaller than the area of the current loop α′2 between the magnetic sensor 10′ and the connection terminals 20 and 30 in the current loop α′ formed by the wiring in the neighborhood of the magnetic sensor 10′ (FIG. 1B).

### (Sensitive Circuit 12)

Here, the sensitive circuit 12 in the magnetic sensor 10 will be described. Note that the sensitive circuits 12A and 12B have the same configuration.

FIGS. 3A and 3B illustrate an example of the sensitive circuit 12. FIG. 3A is a plan view and FIG. 3B is a cross-sectional view along the IIIB-IIIB line in FIG. 3A. In FIG. 3A, the right direction of the page is the +x direction, the upward direction of the page is the +y direction, and the front side direction of the page is the +z direction. In FIG. 3B, the right direction of the page is the +x direction, the upward direction of the page is the +z direction, and the backside direction of the page is the +y direction.

With reference to the plan view in FIG. 3A, the planar structure of the sensitive circuit 12 will be described. Here, the description will be given on the assumption that the sensitive circuit 12 is provided on the substrate 11. The substrate 11 has a quadrangular planar shape, as an example. The planar shape of the substrate 11 is several millimeters square to several tens of millimeters square. For example, the length in the x direction is 3 mm to 20 mm, and the length in the y direction is 3 mm to 20 mm. Note that the planar shape of the substrate 11 may not be quadrangular and the size thereof may be other values.

The sensitive circuit 12 includes: the plural sensitive parts 121 disposed in parallel; connection parts 122 each serially connecting the sensitive parts 121 windingly (a meander structure); and the terminal parts 123 and 124. In the sensitive circuit 12, the terminal parts 123 and 124 are provided to one end portion and the other end portion, respectively, of the sensitive parts 121 connected by the connection parts 122.

The sensitive part 121 has a reed-shaped planar shape with a longitudinal direction and a short direction. It is assumed that, in the sensitive part 121 shown in FIG. 3A, the x direction is the longitudinal direction, and the y direction is the short direction. Then, in FIG. 3A, four sensitive parts 121 are disposed in parallel in the y direction. The sensitive part 121 reveals the magnetic impedance effect. Therefore, the magnetic sensor 10 or the sensitive circuit 12 is sometimes referred to as a magnetic impedance element. The sensitive part 121 is referred to as a sensitive element in some cases.

Each sensitive part 121 has, for example, the length in the longitudinal direction of 1 mm to 10 mm, and the width in the short direction of 50 μm to 150 μm. The thickness thereof is 0.2 μm to 5 μm. The interval between the adjacent sensitive parts 121 is 50 μm to 150 μm. The number of sensitive parts 121 is four in FIG. 3A, but other numbers may be accepted.

Note that the size (the length, the area, the thickness, etc.) of each sensitive part 121, the number of sensitive parts 121, the intervals between the sensitive parts 121, or the like may be set in accordance with the magnitude of the magnetic field to be sensed, in other words, to be detected. Note that the number of the sensitive parts 121 may be one.

The connection part 122 is provided between end portions of the adjacent sensitive parts 121 to connect the plural sensitive parts 121 in series. In other words, the connection part 122 connects the adjacent sensitive parts 121 windingly. In the magnetic sensor 10 including the four sensitive parts 121 shown in FIG. 3A, there are three connection parts 122. The number of connection parts 122 differs depending on the number of sensitive parts 121. For example, if there are five sensitive parts 121, there are four connection parts 122. Moreover, if there is one sensitive part 121, no connection part 122 is provided. Note that the width of the connection part 122 may be set in accordance with the electrical current, etc., to be applied to the sensitive circuit 12. For example, the width of the connection part 122 may be the same as that of the sensitive part 121.

In FIG. 3A, the terminal part 123 is provided on the lower side (the −y direction side) of the page, and the terminal part 124 is provided on the upper side (the +y direction side) of the page. The terminal parts 123 and 124 may have a size capable of connecting to the circuit. Note that, in the sensitive circuit 12 shown in FIG. 3A, since there are four sensitive parts 121, the terminal parts 123 and 124 are provided on the right side (the +x direction side) of the page. In the case where the number of sensitive parts 121 is an odd number, the terminal parts 123 and 124 may be divided to be provided into right and left sides (the ±x direction sides) of the page. Note that the sensitive circuit 12 may be configured by horizontally flipping.

As described above, in the sensitive circuit 12, the sensitive parts 121 are windingly connected in series by the connection parts 122, and the high-frequency currents flow from the terminal parts 123 and 124. Therefore, since the circuit is the path through which high-frequency current flows (here, referred to as the current path), the circuit is referred to as the sensitive circuit 12.

With reference to the cross-sectional view in FIG. 3B, the cross-sectional structure of the sensitive circuit 12 will be described. Here, the description focuses on the sensitive part 121 of the sensitive circuit 12. Note that the substrate 11 is shown together.

The sensitive circuit 12 is provided on the substrate 11. The sensitive circuit 12 includes, as an example, four soft magnetic material layers 111a, 111b, 111c, and 111d from the substrate 11 side. Then, the sensitive circuit 12 includes, between the soft magnetic material layer 111a and the soft magnetic material layer 111b, a magnetic domain suppression layer 112a that suppresses occurrence of a closure magnetic domain in the soft magnetic material layer 111a and the soft magnetic material layer 111b. Further, the sensitive circuit 12 includes, between the soft magnetic material layer 111c and the soft magnetic material layer 111d, a magnetic domain suppression layer 112b that suppresses occurrence of a closure magnetic domain in the soft magnetic material layer 111c and the soft magnetic material layer 111d. Also, the sensitive circuit 12 includes, between the soft magnetic material layer 111b and the soft magnetic material layer 111c, a conductor layer 113 that reduces resistance (here, refer to the electrical resistance) of the sensitive circuit 12. In the case where the soft magnetic material layers 111a, 111b, 111c, and 111d are not distinguished, the layers are referred to as the soft magnetic material layers 111. In the case where the magnetic domain suppression layers 112a and 112b are not distinguished, the layers are referred to as the magnetic domain suppression layers 112.

The substrate 11 is composed of a non-magnetic material; for example, an electrically-insulated oxide substrate, such as glass or sapphire, a semiconductor substrate, such as silicon, or a metal substrate, such as aluminum, stainless steel, or a nickel-phosphorus-plated metal. Note that, in the case where the substrate 11 is composed of a semiconductor substrate, such as silicon, or a metal substrate, such as aluminum, stainless steel, or a nickel-phosphorus-plated metal, and has high conductivity, an insulating material layer to electrically insulate the substrate 11 from the sensitive circuit 12 may be provided on the surface of the substrate 11 on which the sensitive circuit 12 is to be provided.

Examples of the insulating material constituting the insulating material layer include oxide, such as SiO₂, Al₂O₃, or TiO₂, or nitride, such as Si₃N₄ or A1N. Here, description will be given on the assumption that the substrate 11 is made of glass. The thickness of such a substrate 11 is, for example, 0.3 mm to 2 mm. Note that the thickness of the substrate 11 may have other values.

The soft magnetic material layer 111 is configured with a soft magnetic material of an amorphous alloy showing the magnetic impedance effect. As the soft magnetic material constituting the soft magnetic material layer 111, an amorphous alloy, which is an alloy containing Co as a main component doped with a high melting point metal, such as Nb, Ta or W, may be used. Examples of such an alloy containing Co as a main component include CoNbZr, CoFeTa, CoWZr, and CoFeCrMnSiB. The thickness of the soft magnetic material layer 111 is, for example, 100 nm to 1 μm. Here, the soft magnetic material has a small, so-called coercive force, the soft magnetic material being easily magnetized by an external magnetic field, but, upon removal of the external magnetic field, quickly returning to a state with no magnetization or a little magnetization.

In addition, in this specification, amorphous alloys and amorphous metals refer to those having structures that do not have a regular arrangement of atoms such as crystals, which are formed by the sputtering method, etc.

The magnetic domain suppression layer 112 prevents the closure magnetic domain from being generated in the upper and lower soft magnetic material layers 111 that sandwich the magnetic domain suppression layer 112.

In general, in the soft magnetic material layer 111, plural magnetic domains with different directions of magnetization are likely to be formed. In this case, a closure magnetic domain showing annular-shaped magnetization direction is formed. As the external magnetic field is increased, the magnetic domain walls are displaced; thereby the area of the magnetic domain with the magnetization direction that is the same as the direction of the external magnetic field is increased, whereas the area of the magnetic domain with the magnetization direction that is opposite to the direction of the external magnetic field is decreased. Then, as the external magnetic field is further increased, in the magnetic domain where the magnetization direction is different from the direction of the external magnetic field, magnetization rotation is generated so that the magnetization direction is the same as the direction of the external magnetic field. Finally, the magnetic domain wall that existed between the adjacent magnetic domains disappears and the adjacent magnetic domains become a magnetic domain (a single magnetic domain). In other words, when the closure magnetic domain is formed, as the external magnetic field changes, the Barkhausen effect, in which the magnetic domain walls constituting the closure magnetic domain are displaced in a stepwise and discontinuous manner, is generated. The discontinuous displacement of the magnetic domain walls result in noise in the magnetic sensor 10, which causes a risk of reduction in S/N in the output obtained from the magnetic sensor 10. The magnetic domain suppression layer 112 suppresses formation of plural magnetic domains with small areas in the soft magnetic material layers 111 provided on upper and lower sides of the magnetic domain suppression layer 112. This suppresses the formation of the closure magnetic domain and suppresses the noise generated by discontinuous displacement of the magnetic domain walls. Note that, in the case where the magnetic domain suppression layer 112 is provided, it is better to have less magnetic domains to be formed, that is, the effect of increasing the size of the magnetic domains can be obtained, as compared to the case where the magnetic domain suppression layer 112 is not provided.

Examples of materials of such a magnetic domain suppression layer 112 include non-magnetic materials, such as Ru and SiO₂, and non-magnetic amorphous metals, such as CrTi, AlTi, CrB, CrTa, and CoW. The thickness of such a magnetic domain suppression layer 112 is, for example, 10 nm to 100 nm.

The conductor layer 113 reduces the resistance of the sensitive circuit 12. In other words, the conductor layer 113 has conductivity higher than that of the soft magnetic material layer 111, and reduces the resistance of the sensitive circuit 12, as compared to the case where the conductive layer 113 is not included. The magnetic field is detected by the change in the impedance (hereinafter, referred to as the impedance Z, and the change in the impedance is referred to as ΔZ) when the alternating current is passed between the terminal parts 123 and 124 of the sensitive circuit 12. On this occasion, as the frequency of the alternating current is higher, the rate of change in the impedance Z with respect to the change in the external magnetic field ΔZ/ΔH (hereinafter, referred to as the impedance change rate ΔZ/ΔH) (the change in the external magnetic field is referred to as ΔH) is increased. However, if the frequency of the alternating current is increased without including the conductor layer 113, the impedance change rate ΔZ/ΔH is reduced by the floating capacitance. Consequently, the conductor layer 113 is provided to reduce the resistance of the sensitive circuit 12.

As such a conductor layer 113, it is preferable to use metal or an alloy having high conductivity, and is more preferable to use metal or an alloy that is highly conductive and non-magnetic. Examples of materials of such a conductor layer 113 include metal, such as Ag, Al, and Cu. The thickness of the conductor layer 113 is, for example, 10 nm to 1 μm. It is sufficient that the conductor layer 113 can reduce the resistance of the sensitive circuit 12, as compared to the case where the conductor layer 113 is not included.

Note that the upper and lower soft magnetic material layers 111 sandwiching the magnetic domain suppression layer 112 and the upper and lower soft magnetic material layers 111 sandwiching the conductor layer 113 are antiferromagnetically coupled (AFC) with each other. Due to the upper and lower soft magnetic material layers 111 that are antiferromagnetically coupled, occurrence of demagnetizing fields is suppressed and the sensitivity of the magnetic sensor 10 is improved.

(Operation of sensitive circuit 12)

Subsequently, the operation of the sensitive circuit 12 will be described.

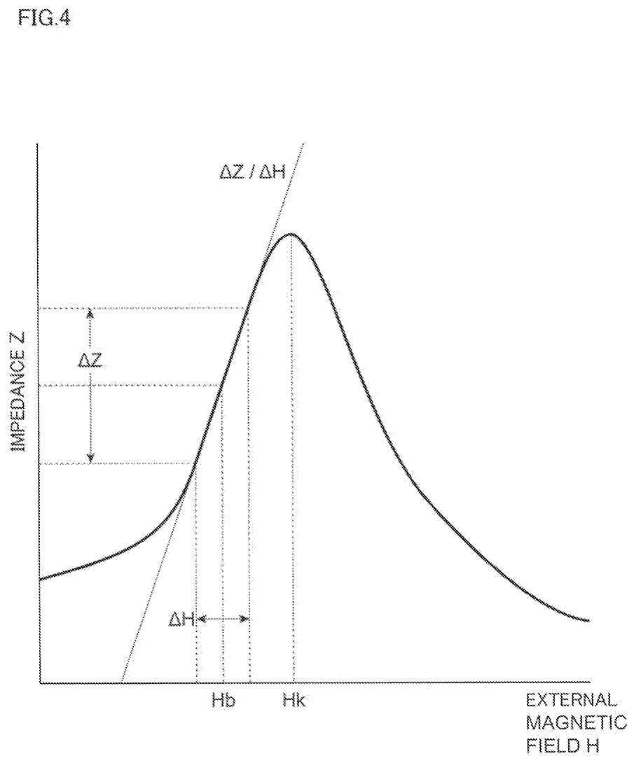

FIG. 4 illustrates the relation between the external magnetic field H applied in the longitudinal direction of the sensitive parts 121 of the sensitive circuit 12 and the impedance Z of the sensitive circuit 12. In FIG. 4, the horizontal axis indicates the external magnetic field H, and the vertical axis indicates the impedance Z. Note that the impedance Z is measured by passing the alternating current between the terminal parts 123 and 124 of the sensitive circuit 12 shown in FIG. 3A. Therefore, though the impedance Z is the impedance of the sensitive circuit 12, it is referred to as the impedance Z of the magnetic sensor 10 in some cases.

As shown in FIG. 4, the impedance Z of the sensitive circuit 12 is increased as the magnetic field H applied in the longitudinal direction of the sensitive parts 121 is increased. Then, the impedance Z of the sensitive circuit 12 is reduced when the magnetic field H to be applied becomes larger than the anisotropic magnetic field Hk. Within the range in which the magnetic field H to be applied is smaller than the anisotropic magnetic field Hk of the sensitive parts 121, by use of a portion where the amount of changes ΔZ in the impedance Z with respect to the amount of changes ΔH in the magnetic field H is steep (ΔZ/ΔH is large), it is possible to extract extremely weak changes in the magnetic field H as the amount of changes ΔZ in the impedance Z. In FIG. 4, the center of the magnetic field H where ΔZ/ΔH is large is shown as the magnetic field Hb. In other words, it is possible to measure the amount of changes (ΔH) in the magnetic field H in the vicinity to the magnetic field Hb (the range indicated by arrows in FIG. 4) with high accuracy. Here, in the portion where the amount of changes ΔZ in the impedance Z is the steepest (ΔZ/ΔH is the largest), the magnetic impedance effect becomes larger and the magnetic field or changes in the magnetic field can be easily measured. To put it another way, the sensitivity becomes higher as the changes in the impedance Z with respect to the magnetic field H are steeper. The magnetic field Hb is referred to as a bias magnetic field in some cases. Hereinafter, the magnetic field Hb is referred to as the bias magnetic field Hb. Note that, as the frequency of the alternating current applied to the sensitive circuit 12 is higher, the sensitivity becomes higher.

(Manufacturing Method of Sensitive circuit 12)

The sensitive circuit 12 is manufactured as follows.

First, on the substrate 11, a photoresist pattern to cover portions excluding the planar shape of the sensitive circuit 12 is formed by using the photolithography technique that is publicly known. Subsequently, on the substrate 11, the soft magnetic material layer 111a, the magnetic domain suppression layer 112a, the soft magnetic material layer 111b, the conductor layer 113, the soft magnetic material layer 111c, the magnetic domain suppression layer 112b, and the soft magnetic material layer 111d are deposited in this order by, for example, the sputtering method. Then, the soft magnetic material layer 111a, the magnetic domain suppression layer 112a, the soft magnetic material layer 111b, the conductor layer 113, the soft magnetic material layer 111c, the magnetic domain suppression layer 112b, and the soft magnetic material layer 111d deposited on the photoresist are removed with the photoresist. Consequently, on the substrate 11, a laminated body configured with the soft magnetic material layer 111a, the magnetic domain suppression layer 112a, the soft magnetic material layer 111b, the conductor layer 113, the soft magnetic material layer 111c, the magnetic domain suppression layer 112b, and the soft magnetic material layer 111d processed into the planar shape of the sensitive element 12 is left. In other words, the sensitive circuit 12 is formed.

As described above, the soft magnetic material layer 111 is provided with uniaxial magnetic anisotropy in a direction crossing the longitudinal direction, for example, the short direction (the y direction in FIG. 2A). The uniaxial magnetic anisotropy can be imparted by performing, for example, the heat treatment at 400° C. in a rotating magnetic field of 3 kG (0.3T) (heat treatment in the rotating magnetic field) and the heat treatment at 400° C. in a static magnetic field of 3 kG (0.3T) (heat treatment in the static magnetic field) subsequent thereto on the sensitive circuit 12 formed on the substrate 11. Impartation of the uniaxial magnetic anisotropy may be performed in depositing the soft magnetic material layers 111 constituting the sensitive circuit 12 by use of a magnetron sputtering method, instead of being performed in the heat treatment in the rotating magnetic field and heat treatment in the static magnetic field. In other words, by the magnetic field formed by the magnets used in the magnetron sputtering method, the soft magnetic material layers 111 are deposited, and at the same time, the uniaxial magnetic anisotropy is imparted to the soft magnetic material layers 111.

In the manufacturing method described above, the sensitive parts 121, the connection parts 122, and the terminal parts 123 and 124 of the sensitive circuit 12 are simultaneously formed. Note that, apart from the sensitive parts 121, the connection parts 122 and the terminal parts 123 and 124 may be formed with a metal having conductivity, such as Al, Cu, Ag, or Au. In addition, the metal having conductivity, such as Al, Cu, Ag, or Au, may be laminated on the connection parts 122 and/or the terminal parts 123 and 124 that are formed simultaneously with the sensitive parts 121. Note that the sensitive circuit 12 was assumed to include the magnetic domain suppression layer 112 and the conductor layer 113; however, it is not necessary to include the magnetic domain suppression layer 112, or the conductor layer 113, or both.

### (Magnetic Sensor 10 to Which the First Exemplary Embodiment is Applied)

The magnetic sensor 10 to which the first exemplary embodiment is applied will be described in detail.

As described above, as the area of the current loop α formed by the wiring in the neighborhood of the magnetic sensor 10 is reduced, the inductance is reduced, and the sensitivity is improved. In the magnetic sensor 10 to which the first exemplary embodiment is applied, as shown in FIG. 1A, two sensitive circuits 12 are connected in series in an overlapping manner, and thereby the area of the current loop α is reduced as compared to a case where the sensitive circuits 12 are not overlapped.

In addition, when the high-frequency current flows through the sensitive circuit 12, a magnetic field surrounding the current path is generated. The magnetic field that has been generated then generates a current in the current path. In other words, the high-frequency current flowing through the sensitive circuit 12 generates a magnetic field, which causes noise affecting the high-frequency current that flows. Consequently, S/N of the magnetic sensor 10 is reduced.

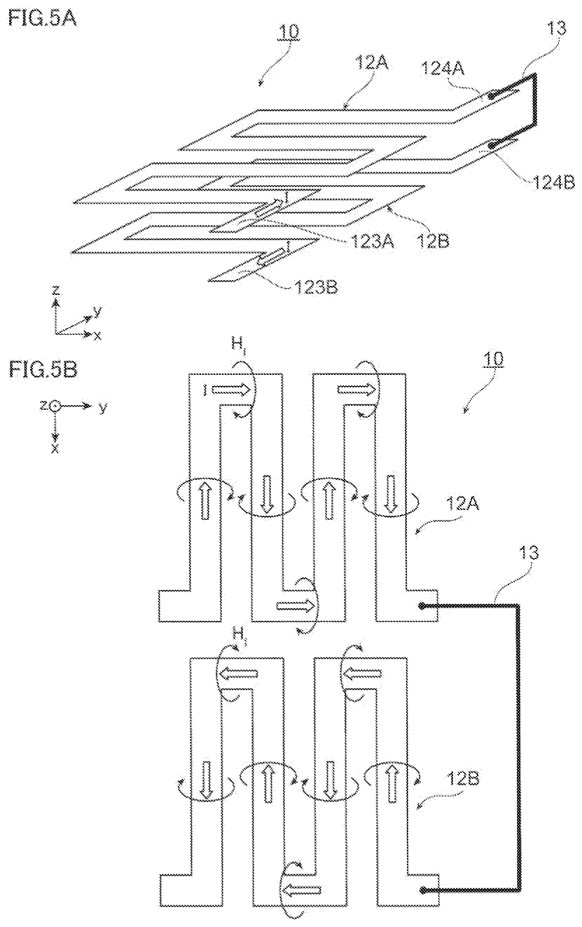

FIGS. 5A and 5B illustrate the configuration of the magnetic sensor 10 to which the first exemplary embodiment is applied. FIG. 5A is a perspective view of the magnetic sensor 10, and FIG. 5B illustrates the current and the magnetic field in the sensitive circuit 12. The x, y, and z directions in FIGS. 5A and 5B correspond to those in FIG. 3A.

The magnetic sensor 10 is configured by overlapping the sensitive circuits 12A and 12B. In other words, the sensitive circuits 12A and 12B have the same planar shape, and in the plan view, the sensitive part 121, the connection part 122, and the terminal parts 123A and 124A of the sensitive circuit 12A are disposed to overlap the sensitive part 121, the connection part 122, and the terminal parts 123B and 124B of the sensitive circuit 12B, respectively. Note that the plane plan view refers to viewing the magnetic sensor 10 from the z direction through the substrate 11. Then, the terminal part 124A of the sensitive circuit 12A and the terminal part 124B of the sensitive circuit 12B are connected by the connection line 13. The terminal part 123A of the sensitive circuit 12A is connected to the connection terminal 20, and the terminal part 123B of the sensitive circuit 12B is connected to the connection terminal 30 (refer to FIG. 1A).

The connection line 13 is configured with a conductive material. Examples of such a conductive material include Al, Cu, Au, Ag, and an alloy of those metals. That is to say, the sensitive circuits 12A and 12B are electrically connected to each other at each one end portion thereof.

The distance between the centers of the terminal part 123A of the sensitive circuit 12A and the terminal part 123B of the sensitive circuit 12B is short compared to the distance between the centers of the terminal part 123A and the terminal part 124A of the sensitive circuit 12A or the distance between the centers of the terminal part 123A of the sensitive circuit 12A and the terminal part 124B of the sensitive circuit 12B. Consequently, as shown in FIG. 1A, the current loop α2 between the magnetic sensor 10 and the connection terminals 20 and 30 is smaller than the current loop α′2 between the magnetic sensor 10′ and the connection terminals 20 and 30 shown in FIG. 1B.

Note that the area of the current loop α1 in the magnetic sensor 10 is the area between the sensitive circuit 12A and the sensitive circuit 12B.

Therefore, the area of the current loop α (α1+α2) formed by the wiring in the neighborhood of the magnetic sensor 10 shown in FIG. 1A is smaller than the area of the current loop α′ (α′1+α′2) formed by the wiring in the neighborhood of the magnetic sensor 10′ shown in FIG. 1B. This reduces the inductance.

The high-frequency current flows between the terminal part 123A of the sensitive circuit 12A and the terminal part 123B of the sensitive circuit 12B. Due to being the high-frequency current, the direction of the current flowing between the terminal part 123A of the sensitive circuit 12A and the terminal part 123B of the sensitive circuit 12B is alternately switched. FIG. 5A shows the directions of current when the current flows from the terminal part 123A of the sensitive circuit 12A to the terminal part 123B of the sensitive circuit 12B with hollow arrows I. Since the sensitive circuits 12A and 12B are connected in series, the current flowing through the sensitive circuit 12A and the current flowing through the sensitive circuit 12B have the same magnitude and opposite flowing directions.

FIG. 5B shows the sensitive circuits 12A and 12B overlapped in the magnetic sensor 10 in a manner shifted from each other and disposed in parallel on the xy plane. FIG. 5B shows the case in which the current I flows from the terminal part 123A of the sensitive circuit 12A to the terminal part 123B of the sensitive circuit 12B. In FIG. 5B, the flowing direction of the current I is indicated by the hollow arrows.

As shown in FIG. 5B, the overlapped sensitive circuits 12A and 12B have the same magnitude and opposite flowing directions of the current I. Therefore, the magnitude of the magnetic field H_{I} generated to surround the current path of the sensitive circuit 12A is equal to the magnitude of the magnetic field H_{I} generated to surround the current path of the sensitive circuit 12B, and the directions thereof are opposite. In other words, the magnetic field generated by the sensitive circuit 12A and the magnetic field generated by the sensitive circuit 12B cancel out each other. Consequently, the magnetic field generated in the magnetic sensor 10 by the high-frequency current flowing through the sensitive circuits 12A and 12B is weaker than the case of the magnetic sensor 10′ including only the sensitive circuit 12A or the sensitive circuit 12B (refer to FIG. 1B). This reduces noise that affects the high-frequency current caused by the generation of the magnetic field. Therefore, the sensitivity-to-noise ratio (the S/N ratio) of the magnetic sensor 10 is improved. Note that, in FIG. 5B, the magnetic fields generated by the current I are denoted as the magnetic fields H_{I} and are indicated by arc-shaped arrows.

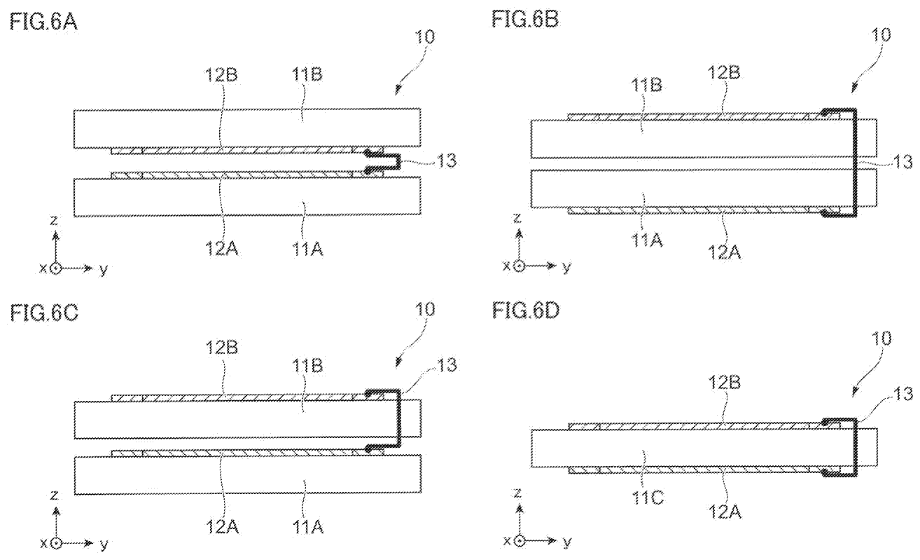

FIGS. 6A to 6D illustrate manners of overlapping the two sensitive circuits 12 (the sensitive circuits 12A and 12B) in the magnetic sensor 10. FIG. 6A shows disposition of the two sensitive circuits 12A and 12B facing each other inside the substrates, FIG. 6B shows disposition of the two sensitive circuits 12A and 12B facing each other outside the substrates, FIG. 6C shows disposition of the two sensitive circuits 12A and 12B that are piled on the substrates 11A and 11B, respectively, and FIG. 6D shows disposition of the two sensitive circuits 12A and 12B provided on the front and back of a single substrate 11C. The sensitive circuits 12A and 12B shown in FIGS. 6A to 6D are cross-sectional views along the VI-VI line in FIG. 3A. Then, the substrates 11 on which the sensitive circuits 12A and 12B are provided are assumed to be the substrates 11A and 11B. The substrate 11 in FIG. 6D is referred to as the substrate 11C. Note that the substrate 11A is an example of a first substrate, and the substrate 11B is an example of a second substrate.

In the magnetic sensor 10 shown in FIG. 6A, the sensitive circuit 12B on the substrate 11B is disposed toward the −z direction so that the sensitive circuit 12A provided on the substrate 11A and the sensitive circuit 12B provided on the substrate 11B face each other inside the substrates 11A and 11B. In this case, an insulating material layer may be provided between the sensitive circuit 12A and the sensitive circuit 12B to provide electrical insulation.

In the magnetic sensor 10 shown in FIG. 6B, the sensitive circuit 12A on the substrate 11A is disposed toward the −z direction so that the sensitive circuit 12A provided on the substrate 11A and the sensitive circuit 12B provided on the substrate 11B face each other outside the substrates 11A and 11B.

In the magnetic sensor 10 shown in FIG. 6C, the sensitive circuit 12A provided on the substrate 11A and the sensitive circuit 12B provided on the substrate 11B are piled in the +z direction.

In the magnetic sensor 10 shown in FIG. 6D, the sensitive circuit 12A is provided on the front side of the substrate 11C, and the sensitive circuit 12B is provided on the backside of the substrate 11C.

The manner of overlapping the two sensitive circuits 12 (the sensitive circuits 12A and 12B) in the magnetic sensor 10 may be any of FIGS. 6A to 6D. Note that, in the magnetic sensor 10 shown in FIGS. 6A to 6D, the sensitive parts 121, the connection parts 122, and the terminal parts 123 and 124 of the sensitive circuit 12A and the sensitive parts 121, the connection parts 122, and the terminal parts 123 and 124 of the sensitive circuit 12B face each other, respectively.

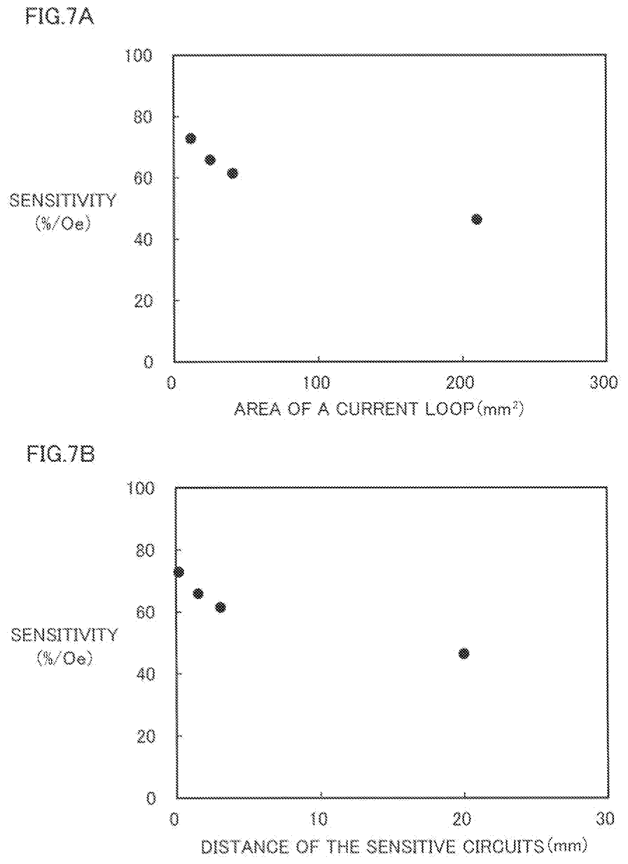

FIGS. 7A and 7B illustrate the sensitivity in the magnetic sensor 10 in which the two sensitive circuits 12 are overlapped. FIG. 7A shows a relation between the area of the current loop and the sensitivity, and FIG. 7B shows a relation between the distance between the two sensitive circuits 12 and the sensitivity. In FIG. 7A, the horizontal axis is the area of the current loop (mm²), and the vertical axis is the sensitivity (%/Oe). In addition, in FIG. 7B, the horizontal axis is the distance between the two sensitive circuits 12 (mm) and the vertical axis is the sensitivity (%/Oe). Note that the sensitivity (%/Oe) is the rate of change in frequency of the magnetic sensor 10 with respect to the strength of the unit signal magnetic field.

Here, the current loop is the addition of the current loop α and the current loop β in FIG. 1A. By changing the distance between the two sensitive circuits 12 (the sensitive circuits 12A and 12B), the area of the current loop is changed. The distance “0.2 mm” between the sensitive circuits 12 in FIG. 7B corresponds to the case in which the sensitive circuits 12A and 12B are disposed to face each other inside the substrates shown in FIG. 6A. The area of the current loop in the magnetic sensor system 1 corresponding thereto is 12 mm². Note that a breakdown of the area 12 mm² of the current loop shows the area 2 mm² of the current loop α formed by the wiring in the neighborhood of the magnetic sensor 10 and the area 10 mm² of the current loop β formed by the wiring in the neighborhood of the detection part 300.

As shown in FIGS. 7A and 7B, when the spacing between the two sensitive circuits 12 increases and thereby the area of the current loop increases, the sensitivity (%/Oe) decreases.

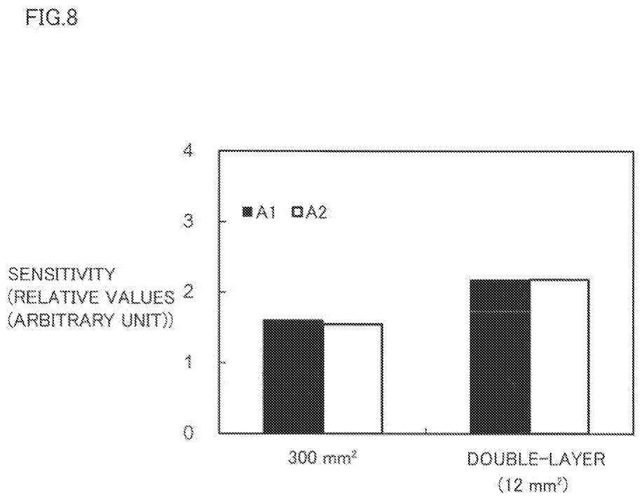

FIG. 8 illustrates the sensitivity in the magnetic sensor 10 in which the two sensitive circuits are overlapped. In FIG. 8, the magnetic sensor 10 is denoted as “double-layer.” In FIG. 8, the “300 mm²,” which is shown for comparison, refers to the case in which the current loop α′ and the current loop ⊕′ are added to obtain the current loop with the area of 300 mm² by use of the magnetic sensor 10′ as described in FIG. 1B. Then, FIG. 8 shows the sensitivity measured in two samples A1 and A2 having the same structure. The vertical axis is the sensitivity, but is represented in relative values (arbitrary unit).

As shown in FIG. 8, the sensitivity in the magnetic sensor 10, in which the two sensitive circuits 12A and 12B are overlapped (“double-layer”), is improved compared to the case in which the area of the current loop using the magnetic sensor 10′ is 300 mm².

### (Focusing Member 17 and Diverging Member 18)

As the density of the magnetic force lines passing through the sensitive circuit 12, namely, the magnetic flux density increases, the sensitivity of the magnetic sensor 10 is improved. To achieve this, the magnetic force lines from the external magnetic field H may be focused on the sensitive circuit 12.

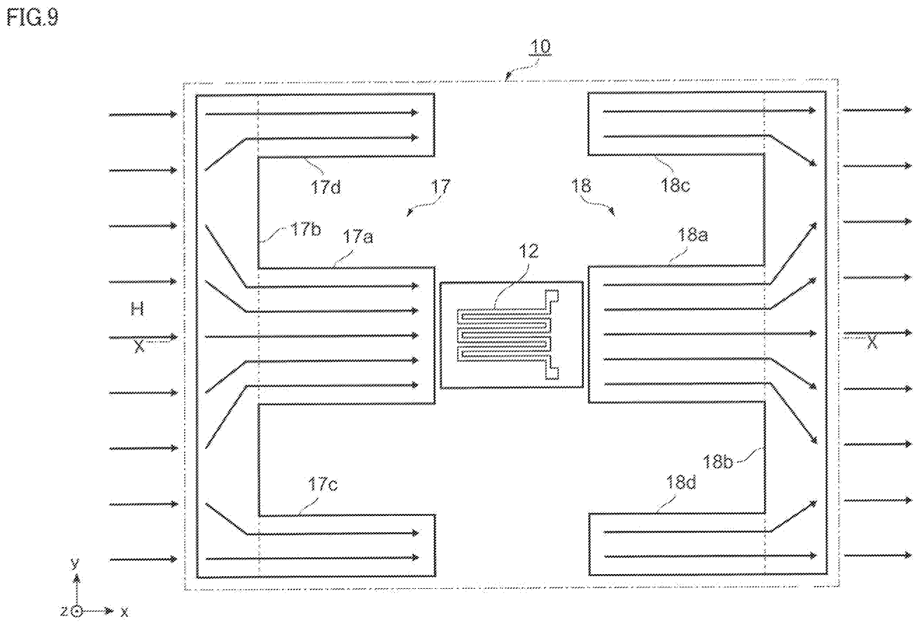

FIG. 9 illustrates the magnetic sensor 10 including a focusing member 17 that focuses the magnetic force lines and a diverging member 18 that diverges the magnetic force lines to the outside. A magnetic sensor including the focusing member 17 and the diverging member 18 is also referred to as the magnetic sensor 10. The x, y and z directions are the same as those in FIGS. 3A and 3B. In FIG. 9, the external magnetic field is denoted as the external magnetic field H and the magnetic force lines are indicated by arrows.

In the magnetic sensor 10, the focusing member 17, the sensitive circuit 12, and the diverging member 18 are arranged in the +x direction in this order. The focusing member 17 focuses the magnetic force lines from the external magnetic field on the sensitive circuit 12. The diverging member 18 diverges the magnetic force lines passed through the sensitive circuit 12 to the outside.

The focusing member 17 includes a facing part 17a that faces the sensitive circuit 12, a wide part 17b having the width that is wider in the y direction than the facing part 17a, and extending parts 17c and 17d each extending in the +x direction from one of both end portions of the wide part 17b. The extending parts 17c and 17d are configured in parallel to the facing part 17a. The facing part 17a is provided at the center portion in the y direction of the wide part 17b. The focusing member 17 has an E shape in a planar shape, in which the wide part 17b serves as a vertical bar and the facing part 17a, the extending parts 17c and 17d serve as respective horizontal bars. The focusing member 17 has a constant thickness in the z direction.

The focusing member 17 is configured so that the width in the y direction of the portion of the facing part 17a that faces the sensitive circuit 12 is wider than the width in the y direction of the sensitive circuit 12. Note that the focusing member 17 may be configured so that the width in the y direction of the portion of the facing part 17a that faces the sensitive circuit 12 is equal to or narrower than the width in the y direction of the sensitive circuit 12.

The diverging member 18 includes a facing part 18a that faces the sensitive circuit 12, a wide part 18b having the width that is wider in the y direction than the facing part 18a, and extending parts 18c and 18d each extending in the -x direction from one of both end portions of the wide part 18b. The extending parts 18c and 18d are configured in parallel to the facing part 18a. The facing part 18a is provided at the center portion in the y direction of the wide part 18b. In other words, similar to the focusing member 17, the diverging member 18 has an E shape in a planar shape. The diverging member 18 has a constant thickness in the +z direction.

The diverging member 18 is configured so that the width in the y direction of the portion of the facing part 18a that faces the sensitive circuit 12 is wider than the width in the y direction of the sensitive circuit 12. Note that the diverging member 18 may be configured so that the width in the y direction of the portion of the facing part 18a that faces the sensitive circuit 12 is equal to or narrower than the width in the y direction of the sensitive circuit 12.

The focusing member 17 and the diverging member 18 are configured with a soft magnetic material. The soft magnetic material has a small, so-called coercive force, the soft magnetic material being easily magnetized by a magnetic field, but, upon removal of the magnetic field, quickly returning to a state with no magnetization or a little magnetization. Here, the focusing member 17 and the diverging member 18 are composed of ferrite, as an example. Examples of such ferrite include those made of MnZn, with an initial permeability of 2500 ±25% and a saturation magnetic flux density Bs of 420 mT. Then, the facing part 17a, the wide part 17b, and the extending parts 17c and 17d of the focusing member 17 are configured as one piece, and the facing part 18a, the wide part 18b, and the extending parts 18c and 18d of the diverging member 18 are configured as one piece.

To additionally describe, the magnetic sensor 10 includes the wide part 17b and the facing part 17a of the focusing member 17, the sensitive circuit 12, the facing part 18a and the wide part 18b of the diverging member 18 arranged in the +x direction in this order. Then, the focusing member 17 and the diverging member 18 have the same E-shaped planar shape, and are arranged symmetrically about the sensitive circuit 12 in the x direction.

As shown in FIG. 9, the magnetic force lines from the external space enter the wide part 17b of the focusing member 17 from the left side of the page (from the -x direction), and a part thereof is focused while proceeding from the wide part 17b to the facing part 17a and exits from the facing part 17a. Note that the other parts of the magnetic force lines that have entered the wide part 17b of the focusing member 17 are focused while proceeding to the extending parts 17c and 17d, and exit from the extending parts 17c and 17d. Then, the magnetic force lines exited from the facing part 17a pass through the sensitive circuit 12 to enter the facing part 18a of the diverging member 18. In addition, each of the magnetic force lines exited from the extending parts 17c and 17d enters the extending parts 18d and 18c, respectively, of the diverging member 18. The magnetic force lines then diverge as proceeding from the facing part 18a, the extending parts 18c and 18d to the wide part 18b, and exit from the wide part 18b to the external space. In other words, the magnetic force lines from the external space are focused by the focusing member 17, and the magnetic flux density, which is the density of the magnetic force lines, is increased to pass through the sensitive circuit 12. In addition, since the magnetic force lines that have passed through the sensitive circuit 12 are diverged by the diverging member 18, the magnetic force lines are prevented from diverging in the sensitive circuit 12, as compared to the case where the diverging member 18 is not provided.

As described above, it is sufficient that the focusing member 17 can focus the magnetic force lines from the external space onto the facing part 17a. For this reason, in the focusing member 17, it is sufficient that the width of the wide part 17b (the width in the y direction) where the magnetic force lines from the external space enter is wider than the width of the facing part 17a (the width in the y direction) where the magnetic force lines exit to the sensitive circuit 12.

In addition, it is sufficient that the diverging member 18 can diverge and output the magnetic force lines to the external space. For this reason, in the diverging member 18, it is sufficient that the width of the facing part 18a (the width in the y direction) where the magnetic force lines from the sensitive circuit 12 enter is narrower than the width of the wide part 18b where the diverged magnetic force lines exit.

Note that, in the focusing member 17 shown in FIG. 9, the facing part 17a is provided at the center portion in the y direction of the wide part 17b, and the extending parts 17c and 17d are provided at respective end portions of the wide part 17b in the ±y direction. However, the facing part 17a may be provided in the +y direction or the -y direction away from the center portion of the wide part 17b. In addition, one of the extending parts 17c and 17d may not be provided. In other words, in the focusing member 17, the facing part 17a may be provided at one end portion in the y direction of the wide part 17b, and the extending part 17c or 17d may be provided at the other end portion in the y direction of the wide part 17b. That is to say, the focusing member 17 may have a C-shaped planar shape (“C-type”). This holds true for the diverging member 18.

Moreover, in the focusing member 17 shown in FIG. 9, the focusing member 17 does not have to include the extending parts 17c and 17d. In this case, the focusing member 17 has a T shape in a planar shape, in which the facing part 17a serves as a vertical bar and the wide part 17b serves as a horizontal bar. This holds true for the diverging member 18.

Further, if the predetermined sensitivity can be obtained in the magnetic sensor 10, it is unnecessary to have the diverging member 18.

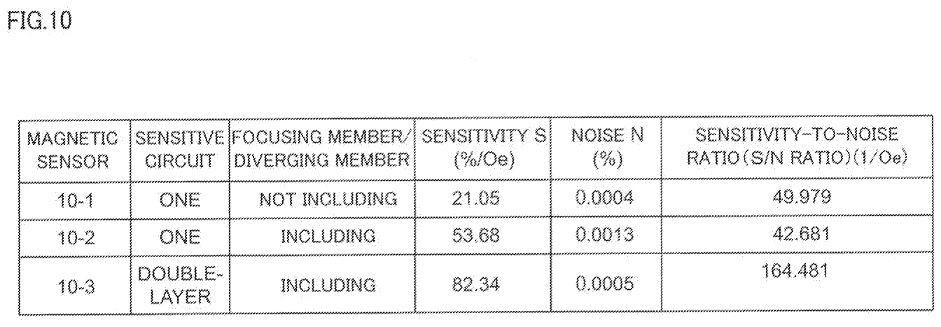

FIG. 10 illustrates a relation among the configuration, the sensitivity S, the noise N, and the sensitivity-to-noise ratio (the S/N ratio) of the magnetic sensor 10. As the configuration of the magnetic sensor 10, the number of sensitive circuits 12 and the presence or absence of the focusing member 17 and the diverging member 18 are shown. The sensitivity S is the rate of change (%/Oe) in the frequency of the magnetic sensor 10 in the unit signal magnetic field, and the noise N is the ratio (%) of the standard deviation of the frequency to the oscillatory frequency, that is, the standard deviation of the oscillatory frequency divided by the oscillatory frequency (standard deviation of oscillatory frequency/oscillatory frequency×100) in each magnetic field. The sensitivity-to-noise ratio (the S/N ratio) (1/Oe) is the sensitivity S divided by the noise N (S/N). FIG. 10 shows three types of magnetic sensors 10. The three types of magnetic sensors 10 are referred to as the magnetic sensors 10-1, 10-2, and 10-3 to distinguish thereof. The magnetic sensor 10-1 includes one sensitive circuit 12 and does not include the focusing member 17 and the diverging member 18. The magnetic sensor 10-2 includes one sensitive circuit 12, the focusing member 17 and the diverging member 18. The magnetic sensor 10-3 includes two overlapped sensitive circuits 12 (the sensitive circuits 12A and 12B), the focusing member 17 and the diverging member 18. For the magnetic sensor 10-3, the sensitive circuit is referred to as “double-layer.”

The magnetic sensor 10-2 has high magnetic flux density by including the focusing member 17 and the diverging member 18; accordingly, the sensitivity S of the magnetic sensor 10-2 is improved as compared to the magnetic sensor 10-1 that does not include the focusing member 17 and the diverging member 18. However, since the noise N generated by the magnetic sensor 10-2 is increased, the sensitivity-to-noise ratio (the S/N ratio) is not improved.

The magnetic sensor 10-3 includes the sensitive circuits 12A and 12B that are overlapped. Since the length of the sensitive parts 121 doubles, the sensitivity S is improved. By overlapping the sensitive circuits 12A and 12B, the current loop α in the magnetic sensors 10-3 is smaller than the current loop in the magnetic sensor 10-2 that does not overlap the sensitive circuits 12 (corresponding to the current loop α′ shown in FIG. 1B). This reduces the noise generated by the current loop α and the noise picked up by the current loop α. Further, the currents I flowing through the sensitive circuits 12A and 12B have the same size and opposite directions. Consequently, the magnetic fields Hi generated by the currents I cancel out each other. Therefore, in the magnetic sensor 10-3, the state of low noise N is maintained. This improves the sensitivity-to-noise ratio (the S/N ratio) of the magnetic sensor 10-3.

In the magnetic sensor 10 of the first exemplary embodiment, it is just needed to suppress the noise N generated by the magnetic fields caused by the currents and improve the sensitivity-to-noise ratio (the S/N ratio) by overlapping the two sensitive circuits 12A and 12B. Therefore, it is not necessary for the sensitive circuits 12A and 12B to have the same planar shape, and at least a part of the current path of the sensitive circuit 12A and at least a part of the current path of the sensitive circuit 12B may be overlapped in the plan view.

### Second Exemplary Embodiment

The magnetic sensor 10 to which the first exemplary embodiment is applied is configured by overlapping the two sensitive circuits 12 (the sensitive circuits 12A and 12B). In contrast thereto, a magnetic sensor 40 to which the second exemplary embodiment is applied is configured by overlapping the one sensitive circuit 12 and a current circuit 15, the current path of which overlaps the current path of the sensitive circuit 12. In the following description, the one sensitive circuit 12 is the same as the sensitive circuit 12A described in the first exemplary embodiment, and accordingly, referred to as the sensitive circuit 12A.

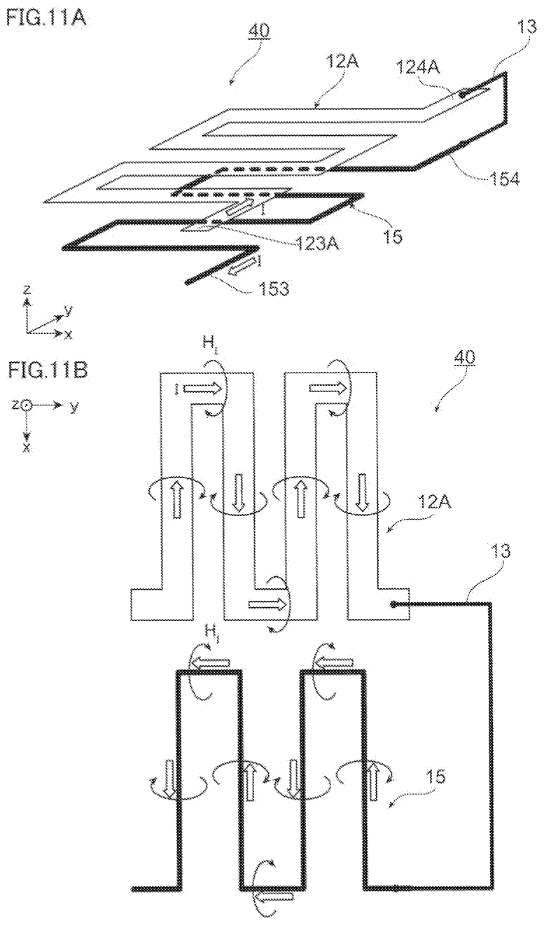

FIGS. 11A and 11B illustrate a configuration of the magnetic sensor 40 to which the second exemplary embodiment is applied. FIG. 11A is a perspective view of the magnetic sensor 40, and FIG. 11B illustrates the currents and the magnetic fields in the sensitive circuit 12 and the current circuit 15. The x, y, and z directions in FIGS. 11A and 11B are the same as those in FIGS. 5A and 5B.

The magnetic sensor 40 is configured by overlapping the sensitive circuit 12A and the current circuit 15. The current circuit 15 has a current path that overlaps the current path of the sensitive circuit 12A. In a plan view, the current circuit 15 is provided with the current path that overlaps the sensitive parts 121, the connection parts 122, and the terminal parts 123A and 124A of the sensitive circuit 12A. Then, the current circuit 15 is provided with a terminal part 153 at a portion facing the terminal part 123A of the sensitive circuit 12A and a terminal part 154 at a portion facing the terminal part 124A of the sensitive circuit 12A. The terminal part 124A of the sensitive circuit 12A and the terminal part 154 of the current circuit 15 facing each other at one end portion are connected by the connection line 13. The terminal part 123A of the sensitive circuit 12A facing the terminal part 153 of the current circuit 15 is connected to the connection terminal 20, and the terminal part 153 is connected to the connection terminal 30 (refer to FIG. 1A). The distance between the centers of the terminal part 123A of the sensitive circuit 12A and the terminal part 153 of the current circuit 15 is short compared to the distance between the centers of the terminal part 123A and the terminal part 124A of the sensitive circuit 12A or the distance between the centers of the terminal part 123A of the sensitive circuit 12A and the terminal part 154 of the current circuit 15. Consequently, similar to the magnetic sensor 10 shown in FIG. 1A, the current loop between the magnetic sensor 40 and the connection terminals 20 and 30 (corresponding to the current loop α2 in FIG. 1A) is smaller than the current loop α′2 between the magnetic sensor 10′ and the connection terminals 20 and 30 shown in FIG. 1B.

Note that the area of the current loop in the magnetic sensor 40 (corresponding to the current loop α1 in FIG. 1A) is the area between the sensitive circuit 12A and the current circuit 15 facing each other. Therefore, there is a small difference between the area of the current loop in the magnetic sensor 40 (corresponding to the current loop α1 in FIG. 1A) and the area of the current loop α1 in the magnetic sensor 10 to which the first exemplary embodiment is applied.

Therefore, the area of the current loop formed by the wiring in the neighborhood of the magnetic sensor 40 (corresponding to the current loop α (α1+α2) shown in FIG. 1A) is smaller than the area of the current loop α′ (α′l+a'2) formed by the wiring in the neighborhood of the magnetic sensor 10′ shown in FIG. 1B. This reduces the inductance.

The current circuit 15 is configured with a non-magnetic conductive material with low magnetic permeability. Examples of such a conductive material include Al, Cu, Au, Ag, and an alloy of those metals.

The high-frequency current flows between the terminal part 123A of the sensitive circuit 12A and the terminal part 153 of the current circuit 15. Due to being the high-frequency current, the direction of the current flowing between the terminal part 123A of the sensitive circuit 12A and the terminal part 153 of the current circuit 15 is alternately switched. FIG. 11A shows the directions of current when the current flows from the terminal part 123A of the sensitive circuit 12A to the terminal part 153 of the current circuit 15 with hollow arrows I. Since the sensitive circuit 12A and the current circuit 15 are connected in series, the current flowing through the sensitive circuit 12A and the current flowing through the current circuit 15 have the same magnitude and opposite flowing directions.

FIG. 11B shows the sensitive circuit 12A and the current circuit 15 overlapped in the magnetic sensor 40 in a manner shifted from each other and disposed in parallel on the xy plane. Then, FIG. 11B shows the case in which the current I flows from the terminal part 123A of the sensitive circuit 12A to the terminal part 153 of the current circuit 15. In FIG. 11B, the flowing direction of the current I is indicated by the hollow arrows.

As shown in FIG. 11B, the overlapped sensitive circuit 12A and current circuit 15 have the same magnitude and opposite flowing directions of the current I. Therefore, the magnitude of the magnetic field H_{I} generated to surround the current path of the sensitive circuit 12A is equal to the magnitude of the magnetic field Hi generated to surround the current path of the current circuit 15, and the directions thereof are opposite. In other words, the magnetic field generated by the sensitive circuit 12A and the magnetic field generated by the current circuit 15 cancel out each other. Consequently, the magnetic field generated in the magnetic sensor 40 by the high-frequency current flowing through the sensitive circuit 12A and the current circuit 15 is weaker than the case of the magnetic sensor 10′ configured with the sensitive circuit 12A (refer to FIG. 1B). This reduces noise that affects the high-frequency current caused by the generation of the magnetic field. Therefore, the sensitivity-to-noise ratio (the S/N ratio) of the magnetic sensor 10 is improved. Note that, in FIG. 11B, the magnetic fields generated by the current I are denoted as the magnetic fields H_{I} and are indicated by arc-shaped arrows.

Note that, in the magnetic sensor 40, the manner of overlapping the sensitive circuit 12A and the current circuit 15 may be the same as those shown in FIGS. 6A to 6D. In other words, the sensitive circuit 12B in FIGS. 6A to 6D may be replaced with the current circuit 15.

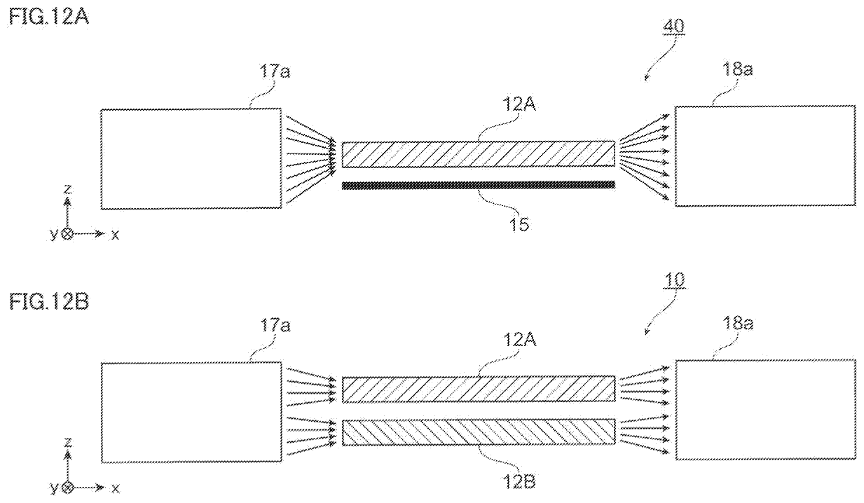

FIGS. 12A and 12B are diagrams illustrating the magnetic sensor 10 to which the first exemplary embodiment is applied and the magnetic sensor 40 to which the second exemplary embodiment is applied, respectively, by comparison thereof. FIG. 12A is a cross-sectional view of the magnetic sensor 40 to which the second exemplary embodiment is applied, and FIG. 12B is a cross-sectional view of the magnetic sensor 10 to which the first exemplary embodiment is applied. Each of the magnetic sensors 10 and 40 includes the focusing member 17 and the diverging member 18. FIGS. 12A and 12B are cross-sectional views along the X-X line in FIG. 9. Note that FIGS. 12A and 12B show the facing part 17a of the focusing member 17 and the facing part 18a of the diverging member 18. FIG. 12A shows the sensitive circuit 12A, the current circuit 15, the focusing member 17 and the diverging member 18, FIG. 12B shows the sensitive circuits 12A and 12B,the focusing member 17 and the diverging member 18, and the other configurations are omitted.

As shown in FIG. 12A, the current circuit 15 included in the magnetic sensor 40 is configured with a conductive material with low magnetic permeability. Therefore, the magnetic force lines (indicated by arrows) from the facing part 17a of the focusing member 17 concentrate on and pass through the sensitive circuit 12A with high magnetic permeability.

As shown in FIG. 12B, in the magnetic sensor 10, the magnetic force lines (arrows) from the facing part 17a of the focusing member 17 are divided into the sensitive circuits 12A and 12B, both of which have high magnetic permeability, to pass through.

In other words, the magnetic flux density in the sensitive circuit 12A of the magnetic sensor 40 is higher than that of the sensitive circuits 12A and 12B of the magnetic sensor 10. Therefore, since the magnetic flux density and sensor output changes of the same level as the magnetic sensor 10 can be obtained with the external magnetic field that is less than that of the magnetic sensor 10, the sensitivity-to-noise ratio (the S/N ratio) is improved in the magnetic sensor 40.

In the magnetic sensor 40 of the second exemplary embodiment, it is just needed to suppress the noise N generated by the magnetic fields caused by the currents and improve the sensitivity-to-noise ratio (the S/N ratio) by overlapping the sensitive circuit 12A and the current circuit 15. Therefore, it is not necessary for the sensitive circuit 12A and the current circuit 15 to completely overlap the current paths in the plan view, and at least a part of the current path of the sensitive circuit 12A and at least a part of the current path of the current circuit 15 may be overlapped in the plan view.

The foregoing description of the exemplary embodiments of the present invention has been provided for the purposes of illustration and description. It is not intended to be exhaustive or to limit the invention to the precise forms disclosed. Obviously, many modifications and variations will be apparent to practitioners skilled in the art. The exemplary embodiments were chosen and described in order to best explain the principles of the invention and its practical applications, thereby enabling others skilled in the art to understand the invention for various embodiments and with the various modifications as are suited to the particular use contemplated. It is intended that the scope of the invention be defined by the following claims and their equivalents.

What is claimed is:

1. A magnetic sensor comprising:
a first sensitive circuit including a sensitive part sensing a magnetic field by magnetic impedance effect; and
a second sensitive circuit including a sensitive part sensing a magnetic field by magnetic impedance effect, wherein
at least a part of a current path of the first sensitive circuit and at least a part of a current path of the second sensitive circuit overlap in a plan view, and one end portion of the first sensitive circuit and one end portion of the second sensitive circuit are electrically connected.

2. The magnetic sensor according to claim 1, wherein currents in portions, which overlap and face each other, of the respective first and second sensitive circuits have opposite flowing directions.

3. The magnetic sensor according to claim 1, wherein each of the first sensitive circuit and the second sensitive circuit has a winding structure.

4. The magnetic sensor according to claim 3, wherein the first sensitive circuit and the second sensitive circuit have a same planar shape in a plan view in a state where the first and second sensitive circuits face each other.

5. The magnetic sensor according to claim 1, wherein the first sensitive circuit is provided on a non-magnetic first substrate and the second sensitive circuit is provided on a non-magnetic second substrate.

6. The magnetic sensor according to claim 1, wherein the first sensitive circuit is provided on a front side of a non-magnetic substrate and the second sensitive circuit is provided on a back side of the substrate.

7. The magnetic sensor according to claim 1, wherein the first sensitive circuit and the second sensitive circuit are connected in series.

8. A magnetic sensor comprising:
a sensitive circuit including a sensitive part sensing a magnetic field by magnetic impedance effect; and
a current circuit configured with a non-magnetic conductive material, wherein
at least a part of a current path of the sensitive circuit and at least a part of a current path of the current circuit overlap in a plan view, and one end portion of the sensitive circuit and one end portion of the current circuit are electrically connected.

9. The magnetic sensor according to claim 8, wherein the sensitive circuit is provided on a non-magnetic first substrate and the current circuit is provided on a non-magnetic second substrate.

10. The magnetic sensor according to claim 8, wherein the sensitive circuit is provided on a front side of a non-magnetic substrate and the current circuit is provided on a back side of the substrate.

11. The magnetic sensor according to claim 1, further comprising:
a focusing member configured with a soft magnetic material and focusing magnetic force lines from outside onto the sensitive circuit.

12. The magnetic sensor according to claim 11, further comprising:
a diverging member configured with a soft magnetic material and diverging the magnetic force lines passed through the sensitive circuit to the outside.

13. The magnetic sensor according to claim 12, wherein the focusing member and the diverging member are provided outside of a substrate on which the sensitive circuit is provided.
